(19) United States
(12) Patent Application Publication
(10) Pub. No.: US 2016/0222289 A1
(43) Pub. Date: Aug. 4, 2016

(54) Luminescent composite comprising a polymer and a luminophore and use of this composite in a photovoltaic cell

(71) Applicant: RHODIA OPERATIONS, Paris (FR)

(72) Inventors: Valerie BUISSETTE, Paris (FR); Thierry LE MERCIER, Rosny- sous Bois (FR); Franck AURISSERGUES, Argenteuil (FR)

(21) Appl. No.: 15/024,653

(22) PCT Filed: Sep. 25, 2014
(86) PCT No.: PCT/EP2014/070477

§ 371 Date: Mar. 24, 2016

(30) Foreign Application Priority Data
Sep. 25, 2013 (FR) 13 02230

(51) Int. Cl. C09K 11/77; H01L 31/0232

(52) U.S. Cl. CPC C09K 11/7734; H01L 31/02322

(57) ABSTRACT

The composite of the invention comprises (a) a polymer selected from ethylene/vinyl acetate, polyethylene terephthalate, ethylene tetrafluoroethylene, ethylene trifluorochloroethylene, perfluorinated ethylene-propylene, polyvinyl butyral, polyurethane and silicones; (b) an inorganic phosphor based on at least one element selected from rare earth elements, zinc and manganese, which has an external quantum efficiency of greater than or equal to 40% for at least one excitation wavelength of between 350 nm and 440 nm; an absorption of less than or equal to 10% for a wavelength of greater than 440 nm; a mean particle size of less than 1 μm; and this phosphor has an emission maximum in a range of wavelengths between 440 nm and 900 nm.

The present application claims the priority of the prior French application FR 13 02230 filed at the INPI (French National Industrial Property Institute) on Sep. 25, 2013, the content of which is incorporated entirely with reference to the present application. In case of inconsistency between the present application and the prior French application affecting the clarity of a term, reference is made exclusively to the present application.

The present application relates to a luminescent composite film comprising a polymer and at least one inorganic phosphor and the use of this composite film in a photovoltaic cell.

### TECHNICAL PROBLEM

Currently, photovoltaic technologies are mainly based on silicon technologies. Although the growth of the photovoltaic market is very substantial, one of the main impediments to the development of photovoltaic energy however is the limited conversion efficiency of the cells (from 15% to 17% for commercial modules made of crystalline silicon). This is explained in particular by the fact that only one portion of the solar spectrum can be absorbed by the silicon and converted into electricity. Specifically, more than 50% of the solar spectrum lies in a range that is too energetic or not energetic enough to be sufficiently absorbed.

It has been proposed to incorporate into the cells phosphors that can absorb photons in the range of wavelengths from 320 nm to 450 nm, which is a range that is too energetic to be absorbed effectively by a photovoltaic cell, and which may emit in the range from 450 nm to 900 nm, so that these new visible or near infrared photons are absorbed by the semiconductor, thus increasing the number of photons available for converting into electricity.

However, the incorporation of these phosphors into the constituent components of the cells, for example polymers positioned on glass layers that protect the silicon elements, may reduce the transmission of light to these silicon elements and in fact compromise the desired improvement in efficiency.

The object of the invention is to provide a luminescent composite film that makes it possible to truly improve the conversion efficiency of the cells.

The composite according to the invention thus makes it possible to increase the absolute conversion efficiency of light energy into electrical energy (r) of a photovoltaic cell. The composite also has the role of protecting the cell against UV radiation.

Another characteristic of the composite in film form is that the film must be able to exhibit sufficient mechanical strength in order to be able to be rolled up and/or to be delivered to clients.

The invention

For this purpose, the luminescent composite, characterized in that it comprises:
a polymer selected from ethylene/vinyl acetate (EVA), polyethylene terephthalate, ethylene tetrafluoroethylene, ethylene trifluorochloroethylene, perfluorinated ethylene-propylene, polyvinyl butyral and polyurethane;
at least one inorganic phosphor based on at least one element which is selected from rare earth elements, zinc and manganese, and which has the following characteristics:
   an external quantum efficiency of greater than or equal to 40% for at least one excitation wavelength of between 350 nm and 440 nm;
   an absorption of less than or equal to 10% for a wavelength of greater than 440 nm;
   a mean particle size d50 of less than 1 μm;
   a mean particle size d50 of at least 30 nm;
   an emission maximum in a range of wavelengths between 440 nm and 900 nm.

Other characteristics, details and advantages of the invention will become even more fully apparent on reading the description which will follow and various concrete but non-limiting examples intended to illustrate it.

### FIGURE

FIG. 1 represents the particle size distribution, by volume, measured for the aluminate powder from example 4.

### PRIOR ART

US 2013/0075692 describes light-emitting layers based on “quantum dot” or nanocrystalline type particles dispersed in a polymer which may be EVA, PET, PE, PP, PC, PS, PVDF, etc. Quantum dots are particles for which the size is critical in order for there to be emission of light. The size of the particles varies from 2 nm to 10 nm in general (in [0006] of US 2013/0075692: 2-50 nm). The phosphor particles of the invention have a size that is greater than 20 nm, or else greater than 30 nm, or greater than 50 nm. The composite film according to the invention does not comprise particles of quantum dot type.

WO 2009/115435 describes submicron particles of barium magnesium aluminate that can be used in luminescent devices or as markers in semi-transparent inks. The particles may be incorporated into a polymer matrix such as PC, PMMA or a silicone. That application does not therefore describe the same polymers as those of the present application. The weight fraction of particles may be between 20% and 99%, that is to say a proportion greater than that envisaged in the present invention. The thickness of the layer comprising the particles dispersed in the polymer is between 30 nm and 10 μm. Furthermore, no mention is made of the photovoltaic application.

FR 2792460 describes a photovoltaic generator comprising a photovoltaic cell and a transparent matrix which may be made of PMMA.

WO 2012/032880 describes a composition useful for the manufacture of a photovoltaic module based on a transparent resin and a fluorescent substance of formula (Ba₁₋ₓ₋ₐ M^{I}ₓ) (Mg_{1-y-b} M^{II}_{y}) (Al_{1-z} M^{III}_{z})₁₀ O₁₇:Eu₁, Mn_{b}. The resin preferably results from a polyaddition. It is preferably an acrylic resin. The particles may have a size varying from 0.0001 μm (0.1 nm) to 100 μm, preferably from 0.001 μm (1 nm) to 1 μm. The reduced sizes of the particles are obtained with the aid of coarse grinding techniques (ball mill, jet mill, etc.) but these techniques do not make it possible to obtain aluminates that have a d50 such as in claim 1.

FR 2993409 describes a transparent matrix containing a plurality of optically active constituents that absorb light energy in a first absorption wavelength and re-emit energy in a second wavelength greater than the first wavelength. The transparent matrix may be made of PMMA, PVC, silicone, EVA or PVDF.

### DEFINITIONS

The expression “rare earth element” is understood to mean the elements of the group consisting of yttrium and the elements of the Periodic Table with an atomic number between 57 and 71 inclusive.

The external quantum efficiency (QE) at an excitation wavelength λ_{exc} is evaluated by the ratio, expressed as a percentage, between the integration of the emission of photons from the phosphor of the composite of the invention, in the emission range 400 nm-900 nm, and the number of photons emitted by a reference phosphor, in the same emission wavelength range, when they are excited at the wavelength λ_{exc}. The measurement may be carried out after acquisition of the emission spectrum of the dried suspension on a Jobin-Yvon spectrofluorometer.

The reference phosphor (QE=100%) is a phosphor of barium magnesium aluminate type. It is the product for which the precursor is obtained according to the process described in example 1 of WO 2004/106263. The raw materials used are a boehmite sol (specific surface area of 265 m²/g) containing 0.157 mol Al per 100 g of gel, a 99.5% barium nitrate, a 99% magnesium nitrate and a europium nitrate solution containing 2.102 mol/l of Eu (d=1.5621 g/ml). 200 ml of boehmite sol (i.e. 0.3 mol of Al) are manufactured. Furthermore, the salt solution (150 ml) contains 7.0565 g of Ba(NO₃)₂, 7.9260 g of Mg(NO₃)₂ and 2.2294 g of the Eu(NO₃)₃ solution. The final volume is made up to 405 ml (i.e. 2% of Al) with water (complete dissolution of the salts). The final pH, after mixing the sol and the salt solution, is 3.5. The mixture obtained is spray-dried in an APV® spray drier with an outlet temperature of 145° C. The dried powder is calcined at 900° C. for 2 hours in air. The powder thus obtained is white. The precursor corresponds to the chemical composition Ba_{0.9}Eu_{0.1}MgAl₁₀O₁₇. This precursor product is then mixed with MgF₂ as the flux in a weight proportion of 1% MgF₂ (1 part of MgF₂ per 99 parts of precursor). This mixture is then calcined under an Ar—H₂ (5 vol %) atmosphere at 1550° C. for 4 h. The calcined product is washed at 60° C. in dilute nitric acid for 2 h while stirring, then it is filtered and dried in an oven at 100° C. for 12 h. The phosphor thus obtained constitutes the reference phosphor.

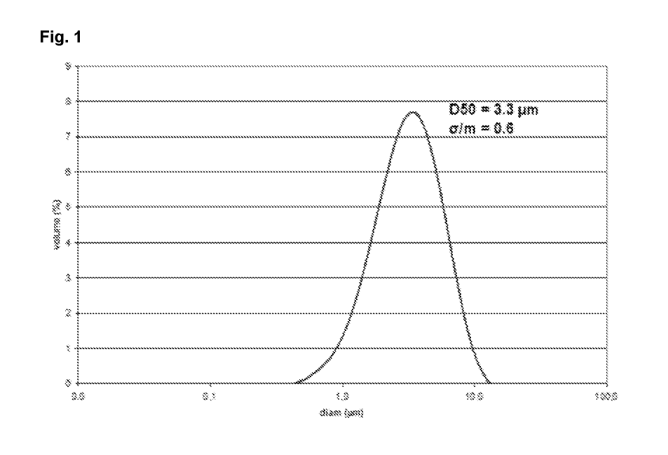

The particle size characteristics and especially the sizes of the particles which are given in the present application are measured using a laser diffractometer, which is a Malvern Mastersizer 2000 device or else a Malvern Zetasizer Nano ZS device. Use is made of the Mastersizer for a d50 >200 nm and of the Zetasizer Nano ZS for a d50<200 nm. The distributions are by volume. The mean size is the mean size (d50) by volume, measured on a suspension of the phosphor diluted in water, without ultrasounds and without a dispersion additive. An example of an illustrative particle size curve is given in FIG. 1 for the aluminate from example 4.

The expression “dispersion index” is understood to mean the ratio:

σ/m=(d₈₄−d₁₆)/2d₅₀

wherein:
d₈₄ is the particle diameter for which 84% of the particles have a diameter smaller than d₈₄;
d₁₆ is the particle diameter for which 16% of the particles have a diameter smaller than d₁₆;
d₅₀ is the mean diameter of the particles.

The term “absorption” is understood to mean the percentage of light absorbed in the range of wavelengths between 400 nm and 780 nm, measured by diffuse reflection on a Perkin Elmer Lambda 900 type UV/visible spectrometer.

### DETAILED DESCRIPTION OF THE INVENTION

Regarding the polymer of the luminescent composite, this polymer (also denoted by P1) may be selected from ethylene/vinyl acetate (EVA), polyethylene terephthalate (PET), a fluoropolymer, polyvinyl butyral and polyurethane.

EVA denotes a copolymer of ethylene and vinyl acetate. The EVA may consist only of these two monomers or else may consist of these two monomers and of at least one other comonomer selected from vinyl esters such as for example vinyl propionate or vinyl benzoate, C1-06 alkyl (meth)acrylates such as for example methyl acrylate or butyl acrylate, or (meth)acrylic acids or salts thereof such as for example methacrylic acid. The EVA may consist of from 55% to 95% by weight of ethylene, from 5% to 40% by weight of vinyl acetate, and from 0 to 5% by weight of another comonomer. The proportion of vinyl acetate may be between 30% and 35%.

The polymer is capable of being extruded in film form. The choice of the polymer is important also because it must make it possible to prepare a film which is capable of being rolled up and being delivered to end-user clients. The polymer is also important for making it possible to obtain a good compromise of mechanical and optical properties necessary for the use of the composite in the targeted application.

This polymer may very particularly be PET or EVA. The polymer of the composite may or may not be crosslinkable.

Regarding the phosphor that is dispersed in the composite, this phosphor must have a certain number of characteristics as regards its absorption and emission properties. It must thus have an external quantum efficiency of greater than or equal to 40% for at least one excitation wavelength of between 350 nm and 440 nm. This external quantum efficiency may be more particularly greater than 50% for at least one excitation wavelength of between 350 nm and 440 nm.

The phosphor absorbs well in the UV and little or not at all in the visible (440-700 nm). Thus, it has an absorption of less than or equal to 10% for a wavelength of greater than 440 nm, preferably of less than 5% and more particularly less than 3%.

It must also be able to exhibit an emission maximum in a range of wavelengths between 440 nm and 900 nm, preferably between 500 nm and 900 nm.

The phosphors of the composite of the invention furthermore have a specific particle size distribution. Specifically, they consist of particles, at least 50% of which have a diameter of less than 1 μm. This mean size d50 may be at most 0.7 μm, especially at most 0.5 μm and more particularly at most 0.3 μm. This mean size d50 is at least 30 nm, more particularly at least 50 nm.

The phosphor may have a d50 between 80 nm and 400 nm, preferably between 80 nm and 300 nm.

Furthermore, these particles may have a narrow particle size dispersion; more specifically their dispersion index may be at most 1, preferably at most 0.7 and more preferably still at most 0.5.

The phosphor of the composite of the invention is selected from the phosphors that contain at least one element selected from rare earth elements, zinc and manganese. According to one embodiment, they contain at least one element selected from rare earth elements, especially the rare earth elements M¹ described further on.

Aluminate Doped by a Rare Earth Element and/or Manganese

The phosphor may be selected from aluminates doped by a rare earth element and/or manganese. These aluminates may be those of formulae AMgAl₁₀O₁₇:Eu²⁺ or AMgAl₁₀O₁₇:Eu²⁺, Mn²⁺, formulae wherein A represents the elements Ba, Sr and Ca alone or in combination. Examples of these aluminates are given below.

BaMgAl₁₀O₁₇:Eu²⁺

BaMgAl₁₀O₁₇:Eu²⁺, Mn²⁺

As other examples of aluminates, mention may be made of those of formula a(M_{1-d}Eu_{d}O).b(Mg₁₋ₑMnₑO).c(Al₂O₃) wherein:

M denotes the elements Ba, Sr and Ca or combinations thereof; and a, b, c, d and e satisfy the relationships:

0.25≦a≦2; 0<b≦2; 3≦c≦9; 0≦d≦0.4 and 0≦e≦0.6.

Europium-doped (halo)phosphates

The phosphors may also be selected from europium-doped phosphates. These phosphates may be those of formula ABPO₄:Eu²⁺ wherein A represents the elements Li, Na and K alone or in combination and B represents the elements Ba, Sr and Ca alone or in combination. Examples of products of this type are given below:

LiCaPO₄:Eu²⁺

LiBaPO₄:Eu²⁺

Europium-doped halophosphates may also be suitable within the context of the invention. These products may correspond to the formula A₅(PO₄)₃X:Eu²⁺ wherein A represents the elements Ba, Sr and Ca alone or in combination, X being OH, F and Cl. Examples of these halophosphates are given below.

Sr₅(PO₄)₃Cl: Eu²⁺

Ca₅(PO₄)₃Cl: Eu²⁺

Rare Earth Oxysulfides

Europium-doped rare earth oxysulfides may also be used as phosphors. These products have a formation of Ln₂O₂S:Eu³⁺ type with Ln representing the elements La, Gd, Y and Lu, alone. An example of such an oxysulfide is given below.

La₂O₂S:EU³⁺

Europium-Doped Rare Earth Vanadates

Europium-doped rare earth vanadates also constitute phosphors. They generally have a formula of LnVO₄:Eu³⁺,Bi³ type with Ln representing the elements La, Gd, Y and Lu, alone or in combination. An example is given below.

YVO₄:Eu³⁺,Bi³⁺

### Other Phosphors

Mention may also be made of the phosphors of formula LnPVO₄, Ln denoting a rare earth element.

Zinc compounds doped with manganese, zinc, silver and/or copper may also be suitable as phosphors. Examples of these compounds are given below.

ZnS:Mn²

ZnS:Ag,Cu

ZnO:Zn

Rare Earth Borates

Cerium-doped rare earth borates may also be used as phosphors. These borates generally have a formula of LnBO₃:Ce³⁺ or LnBO₃:Ce³⁺,Tb³⁺ type wherein Ln represents the elements La, Gd, Y and Lu, alone or in combination.

The phosphors mentioned above may be advantageously prepared by a process of the type described below. This process comprises a first step in which a medium is formed comprising a colloidal suspension and/or salts of the constituent elements (other than oxygen) of the phosphor that it is desired to prepare. Next, a precipitation is carried out by addition of a basic compound to the medium formed above. The precipitate is then separated from the liquid medium, it is dried then calcined in air at a temperature generally between 200° C. and 900° C., preferably between 600° C. and 900° C. A second calcination is then carried out in air or in a reducing atmosphere which makes it possible to obtain a phosphor. This phosphor is then subjected to wet grinding in order to obtain the particle size needed for the implementation of the present invention.

According to one particular embodiment, the phosphor used as element of the composite of the invention in the preparation thereof results from the separation of the solid product from the liquid phase starting from a specific suspension. More specifically, it is a liquid-phase suspension of particles of a rare earth borate, these particles being substantially single-crystal particles having a mean size of between 100 nm and 400 nm.

For the description of this phosphor, reference can be made to patent application WO 2007/042653. Some of the features of this phosphor are recalled below. The particles of the suspension may more particularly have a mean size of between 100 nm and 300 nm and also a dispersion index of at most 0.7.

The rare earth element forming the borate belongs to the group comprising yttrium, gadolinium, lanthanum, lutetium and scandium. The borate may additionally comprise, as dopant, at least one element selected from antimony, bismuth and the rare earth elements other than that forming the borate, it being possible for the dopant rare earth element more particularly to be cerium, terbium, europium, thallium, erbium and praseodymium.

The suspension is obtained by a process in which a rare earth borocarbonate or hydroxyborocarbonate is calcined at a high enough temperature to form a borate and to obtain a product having a specific surface area of at least 3 m²/g; wet grinding of the product resulting from the calcination is then carried out.

For this process, use is made of a rare earth borocarbonate or hydroxyborocarbonate that has been obtained by reaction of a rare earth carbonate or hydroxycarbonate with boric acid, the starting reaction medium being in the form of an aqueous solution.

Use may also be made of a rare earth borocarbonate or hydroxyborocarbonate that has been obtained by a process in which boric acid and a rare earth salt are mixed; the mixture thus obtained is reacted with a carbonate or bicarbonate; finally the precipitate thus obtained is recovered.

In order to obtain a phosphor powder, a separation of the solid product from the liquid phase is carried out, starting from the suspension as obtained at the end of the wet grinding step.

According to another embodiment, the phosphor used as element of the composite of the invention in the preparation thereof results from the separation of the solid product from the liquid phase starting from a specific suspension. More specifically, it is a liquid-phase suspension of a barium magnesium aluminate consisting of substantially single-crystal particles having a mean size of between 80 nm and 400 nm.

For the description of this phosphor, reference can be made to patent application WO 2009/115435. Some of the features of this product are recalled below.

One feature of the constituent particles of the aluminate according to this embodiment of the invention is their single-crystal character. This is because most of these particles, that is to say at least about 90% of them, and preferably all of them, consist of a single crystal. This single-crystal aspect of the particles may be demonstrated in the technique of transmission electron microscopy (TEM) analysis. For suspensions in which the particles are in a d50 size range of at most about 200 nm, the single-crystal aspect of the particles may also be demonstrated by comparing the mean particle size measured by the abovementioned laser diffraction technique with the value of the measurement of the size of the crystal or the coherent domain obtained from X-ray diffraction (XRD) analysis. Use is made, for this measurement, of the Scherrer model, as described in the work “Theorie et technique de la radiocristallographie” [Radiocrystallography theory and technique], A. Guinier, Dunod, Paris, 1956. It is specified here that the XRD measured value corresponds to the size of the coherent domain calculated from the diffraction line corresponding to the crystallographic plane of the main diffraction peak (e.g. [102] crystallographic plane). The two values, laser diffraction mean size and XRD mean size, indeed have the same order of magnitude, that is to say that they are in a (d₅₀ measurement value/XRD measurement value) ratio of less than 2, more particularly of at most 1.5. This is illustrated by example 1.

As a consequence of their single-crystal character, the aluminate particles of the invention are in a well-separated and individual form. There are no or few particle agglomerates. This good individualization of the particles may be demonstrated by comparing the d₅₀ measured by the laser diffraction technique and that measured from an image obtained by transmission electron microscopy (TEM). Use may be made of a transmission electron microscope that gives access to enlargements ranging up to 800 000. The principle of the method consists in examining, under the microscope, various regions (around 10) and in measuring the dimensions of 250 particles deposited on a support (for example after depositing a suspension of the particles on the support and having left the solvent to evaporate), while considering these particles to be spherical particles. A particle is judged to be identifiable when at least half of its perimeter can be defined. The TEM value corresponds to the diameter of the circle that correctly reproduces the circumference of the particle. The identification of the usable particles can be carried out by using Image J, Adobe Photoshop or Analysis software. After having measured the sizes of the particles by the above method, a cumulative particle size distribution of the particles is deduced therefrom, which is regrouped into several particle size categories ranging from 0 to 500 nm, the breadth of each category being 10 nm. The number of particles in each category is the basic data for representing the particle size distribution by number. The TEM value is the median diameter such that 50% of the particles (by number) counted on the TEM images have a diameter smaller than this value. Here too, the values obtained by these two techniques have a (d₅₀ measurement value/TEM measurement value) ratio that is in the same order of magnitude and therefore in the proportions given in the preceding paragraph.

The barium aluminate of this embodiment may correspond to the formula (I) below:

a(Ba_{1-d}M¹_{d}O).b(Mg₁₋ₑM²ₑO).c(Al₂O₃) (I)

wherein:

M¹ denotes a rare earth element which may be more particularly gadolinium, terbium, yttrium, ytterbium, europium, neodymium and dysprosium;

M² denotes zinc, manganese or cobalt;

a, b, c, d and e satisfy the relationships:

0.25≦a≦2; 0<b≦2; 3≦c≦9; 0≦d≦0.4 and 0≦e≦0.6.

More particularly still, M¹ may be europium.

More particularly, M² may be manganese.

More particularly, the aluminate of the invention may correspond to the formula (I) above wherein a=b=1 and c=5. According to another particular embodiment, the aluminate of the invention may correspond to the formula (I) above wherein a=b=1 and c=7. According to another embodiment, e=0. According to another embodiment, d=0.1. According to another embodiment, 0.09 d 0.11. The aluminate may be the one from example 1.

The aluminate may be obtained by a multistep process.

1^{st} step: a liquid mixture is formed comprising, in water, aluminum compounds and compounds of other elements that are incorporated into the composition of the aluminate. The mixture is a solution, a suspension or else a gel. The starting compounds may be inorganic salts or else hydroxides or carbonates. As salts, mention may be made preferably of nitrates, for instance in the case of barium, aluminum, europium and magnesium. Use may also be made of aluminum sulfate, or else of chlorides or acetates. For aluminum, use may also be made of a sol or a colloidal dispersion of aluminum, the size of the particles of which may be between 1 nm and 300 nm. Aluminum may be present in boehmite form.

2^{nd} step: the mixture obtained in the 1^{st} step is dried. The drying may preferably be carried out by spray drying, which has the advantage of properly controlling the size of the particles resulting from the drying. Spray drying consists in spraying the mixture from the 1^{st} step using a spray nozzle. A person skilled in the art knows how to adapt the spray drying parameters (temperature of the mixture before spraying, throughput of the mixture, characteristics of the spray nozzle, pressure in the spray chamber in which the mixture is sprayed, etc.) so as to obtain dry particles. Spraying may be performed using a nozzle of sprinkler-rose type or another type. It is also possible to use atomizers known as turbine atomizers. Reference may be made to the work by Masters entitled “Spray-drying”, 2nd edition, 1976, published by George Godwin. Use may be made of an APV spray dryer. It is also possible to carry out the spray drying operation by means of a “flash” reactor, for example of the type described in French patent applications nos. 2 257 326, 2 419 754 or 2 431 321. This type of spray dryer may be used for preparing particles for which d50 is small. In this case, the hot gases are given a helical motion and flow into a vortex well. The mixture to be dried is injected along a path coincident with the axis of symmetry of the helical paths of said gases, thereby allowing the momentum of the gases to be completely transferred to the mixture to be treated. The gases thus fulfil two functions: firstly, the function of spraying the initial mixture, that is to say converting it into fine droplets, and secondly, the function of drying the droplets obtained. Moreover, the extremely short residence time (for example less than about 1/10th of a second) of the particles in the reactor has the advantage, among others, of limiting any risk of them being overheated as a result of being in contact with the hot gases for too long a time.

Reference may be made to FIG. 1 from French patent application no. 2 431 321. This reactor consists of a combustion chamber and a contact chamber composed of a double cone or a truncated cone whose upper part diverges. The combustion chamber runs into the contract chamber via a narrow passage.

The upper part of the combustion chamber is provided with an opening allowing the combustible phase to be introduced. Moreover, the combustion chamber includes a coaxial internal cylinder, thus defining, inside this chamber, a central region and an annular peripheral region, having perforations located mostly toward the upper part of the apparatus. The chamber has a minimum of six perforations distributed over at least one circle, but preferably over several circles which are spaced apart axially. The total surface area of the perforations located in the lower part of the chamber may be very small, of the order of 1/10th to 1/100th of the total surface area of the perforations of said coaxial internal cylinder.

The perforations are usually circular and of very small thickness. Preferably, the ratio of the perforation diameter to the wall thickness is at least 5, the minimum wall thickness being only limited by the mechanical requirements.

Finally, an angled pipe runs into the narrow passage, the end of which opens along the axis of the central region.

The gas phase given a helical motion (hereinafter referred to as the helical phase) is composed of a gas, generally air, introduced into an orifice made in the annular region, this orifice preferably being located in the lower part of said region.

In order to obtain a helical phase in the narrow passage, the gas phase is preferably introduced at low pressure into the aforementioned office, that is to say at a pressure of less than 1 bar and more particularly at a pressure between 0.2 and 0.5 bar above the pressure existing in the contact chamber. The velocity of this helical phase is generally between 10 and 100 m/s and preferably between 30 and 60 m/s.

Moreover, a combustible phase, which may especially be methane, is injected axially via the aforementioned opening into the central region at a velocity of about 100 to 150 m/s.

The combustible phase is ignited by any known means, in the region where the fuel and the helical phase are in contact with each other.

Thereafter, the flow imposed on the gases in the narrow passage takes place along a number of paths coincident with families of generatrices of a hyperboloid. These generatrices are based on a family of small-sized circles or rings located close to and below the narrow passage, before diverging in all directions.

Next, the mixture to be treated in liquid form is introduced via the aforementioned pipe. The liquid is then divided into a multitude of drops, each drop being transported by a volume of gas and subjected to a motion creating a centrifugal effect. Usually, the flow rate of the liquid is between 0.03 and 10 m/s.

The ratio of the proper momentum of the helical phase to that of the liquid mixture must be high. In particular, it is at least 100 and preferably between 1000 and 10 000. The momenta in the narrow passage are calculated based on the input flow rates of the gas and of the mixture to be treated, and on the cross section of said passage. Increasing the flow rates increases the size of the drops.

Under these conditions, the proper motion of the gases is imposed, both in its direction and its intensity, on the drops of the mixture to be treated, these being separated from one another in the region of convergence of the two streams. The velocity of the liquid mixture is, in addition, reduced to the minimum needed to obtain a continuous flow

The spray drying is generally carried out with a solid output temperature of between 100° C. and 300° C.

3^{rd} step: consists in calcining the product resulting from the 2^{nd} step. This calcination is carried out at a temperature which is high enough to obtain a crystalline phase. This temperature is at least 1100° C., more particularly at least 1200° C. It may be at most 1500° C. It may be between 1200° C. and 1400° C. The calcination is carried out in air and/or in a reducing atmosphere, for example in a hydrogen/nitrogen or hydrogen/argon mixture. The duration of this calcination is for example between 30 min and 10 hours. It is possible to carry out one calcination in air followed by a calcination in a reducing atmosphere.

In certain cases, it may be useful to carry out a calcination prior to the calculation described above, that is to say between the 2^{nd} step and the 3^{rd} step. This prior calcination is carried out at a somewhat lower temperature than the temperature given above, for example below 1000° C., especially between 900° C. and 1000° C.

4^{th} step: consists in carrying out a wet grinding of the product resulting from the 3^{rd} step. The wet grinding can be carried out in water or in a water/water-miscible solvent mixture. The solvent may be an alcohol (e.g. methanol, ethanol) or a glycol (e.g. ethylene glycol) or a ketone (e.g. acetone).

A dispersant, the role of which is to help to stabilize the suspension, may be used for the grinding. Wet grinding is known to a person skilled in the art.

5^{th} step: starting from the suspension obtained in the 4^{th} step, the aluminate is recovered in powder form via a liquid/solid separation, such as for example a filtration optionally followed by a drying operation.

In order to obtain the phosphor in the form of a powder, the process starts with the suspension as obtained at the end of the wet grinding operation and the solid product is separated from the liquid phase using any known separation technique, for example by filtration. Reference may be made to example 1 for further details regarding the process used. In particular, the aluminate preparation process does not comprise a step of calcination of a precursor of the phosphor with a flux such as MgF₂ as in the case of the reference product described above. Indeed, in the presence of such a step, the grinding of the aluminate so as to obtain the particles of the phosphor according to claim 1 is made difficult.

Regarding the composite, the latter was obtained by mixing the polymer and the phosphor, for example by extrusion of such a mixture. It is possible to directly extrude the mixture of the polymer and of the phosphor powder or else to use a masterbatch.

Besides the phosphor, the composite may also comprise standard additives in the field of films for solar cells. The composite may comprise one or more additives selected from antistatic, antioxidant, crosslinking, etc. additives. The crosslinker may be for example one of those described in US 2013/0328149. These additives are introduced during the extrusion.

In the case of a masterbatch, the polymer of the composite film which has been described above (P1) and a masterbatch comprising the phosphor pre-dispersed in a polymer (P2) are extruded. The polymer of the masterbatch P2 may be of the same type as the polymer (P1) of the composite film, or different. The two polymers P1 and P2 are preferably compatible with one another so as to form a homogenous mixture. Thus, for example, in the case where P1 is an EVA, it is possible to use a masterbatch based on a polymer P2 which is the same grade of EVA or another EVA or else a polymer that is compatible with P1, such as for example a polyethylene. The masterbatch is itself prepared by extrusion in an extruder or using a kneader.

In US 2013/0328149, it is taught that the phosphor particles are dispersed in spherical or substantially spherical polymer particles, which are themselves dispersed in the polymer of the composite. These particles are prepared by emulsion polymerization or suspension polymerization. The polymer particles are for example based on PMMA as in example 1 of US 2013/0328149. The dispersion envisaged in US 2013/0328149 necessitates adapting the nature of the polymer particles to the polymer of the composite. It furthermore requires an additional step of preparing the polymer particles. Within the context of the present invention, this technique thus described in US 2013/0328149 is preferably not used, so that the composite does not comprise such polymer particles.

The invention also relates to a process for preparing a composite according to the invention, wherein a polymer P1 and the phosphor, or else the polymer P1 and a masterbatch comprising the phosphor pre-dispersed in a polymer P2, are extruded.

Generally, the amount of phosphor in the polymer may vary between 0.1% and 5%, especially between 0.5% and 2% and more particularly 0.5% and 1% by weight of the phosphor-polymer P1 assembly. When a masterbatch is used, the amount of phosphor is relative to the phosphor-composite film polymer P1-masterbatch polymer P2 assembly.

This composite may be in the form of a film, the mean thickness of which may be between 25 μm and 800 μm and more particularly from 100 μm to 500 μm. The thickness of the film is controlled by adjusting the thickness of the lips. The mean thickness is measured at 25° C. on the film using a micrometer from 20 measurements taken randomly over the entire surface of the film.

This film may be obtained by extrusion. It is possible to use an extruder such as that described in the examples.

The composition according to the invention is also characterized by the fact that formed into a film, the latter may have a total transmission (TT) of at least 85%, measured for a film thickness of 250 μm. The film may also have a determined haze of at most 10%, measured for a film thickness of 250 μm. The total transmission and the haze are determined with a Perkin Elmer UV-Vis Lambda 900 device under the conditions recalled further on at a wavelength of 550 nm.

Regarding the photovoltaic cell, the cell comprises a luminescent composite as described above.

The invention may relate more specifically to conventional solar cells made of crystalline silicon. It may also be applied to second-generation solar cells known as “thin-film” solar cells, which are, for example, cells based on amorphous silicon, cadmium telluride (CdTe) or copper indium gallium selinide (CIGS) and homologues thereof. Finally, it may be applied to third-generation cells such as organic photovoltaic (OPV) systems, and dye-sensitized solar cells (DSSC).

The composite, generally in the form of a film, may be positioned on the front face of the active elements of the cell, for example directly as an encapsulant of these elements or in place of the glass of the cell or as a layer deposited on this glass. An active element of the cell is an element that converts light energy into electricity.

The composite film makes it possible to increase the absolute light energy to electrical energy conversion efficiency (r) of the active elements of the cell, once affixed to the photovoltaic cell. It makes it possible to convert the UV rays into visible radiation absorbed by the active elements, which increases the number of solar photons that can be used. More specifically, the film according to the invention is such that the absolute efficiency of a cell on which the composite film according to the invention is applied is greater than the absolute efficiency of the cell when a composite film of the same thickness and consisting of the same polymer and the same additives but not filled with phosphor is applied: efficiency r of the cell in the presence of an affixed composite film>efficiency of the cell in the presence of a composite film of the same thickness and consisting of the same polymer and same additives but not filled with phosphor (r_{ref}). The improvement (r−r_{ref})/r_{ref}×100 may be at least 5%, or even at least 7%.

The invention therefore also relates to the use of a composite film for increasing the light energy to electrical energy conversion efficiency of a photovoltaic cell.

The invention also relates to a process for converting light energy into electrical energy using a photovoltaic cell that consists in increasing, with the aid of the composite according to the invention, the number of solar photons that can be used by the active elements for the conversion of light energy into electricity.

### EXAMPLES

### Example 1

Preparation of the Phosphor

Use is made, in this example, of a phosphor as described in example 1 of application WO 2009/115435 and of formula Ba_{0.9}Eu_{0.1}MgAl₁₀O₁₇. The product used here is the powder obtained after drying, in an oven and at 60° C., of the suspension which was obtained at the end of the wet grinding step described in this example 1. In the preparation of this phosphor, no flux such as MgF₂ was used.

The mean size of the product measured by laser diffraction is 140 μm. The dispersion σ/m is 0.6.

The size of the coherent domain calculated from the diffraction line corresponding to the [102] plane is 101 nm. Hence a d50 measurement value/XRD measurement value equal to 140/101=1.386. It is observed that the value of d50 (laser) and that of the size of the coherent domain (XRD) have the same order of magnitude, which confirms the single-crystal character of the particles.

The phosphor has an absorption of at most 8% in the range of wavelengths between 500 nm and 750 nm.

Its external quantum efficiency is 51% at an excitation wavelength λ_{exc} of 380 nm. Its emission maximum is located at 450 nm.

Preparation of a Luminescent Composite

A composite film is prepared from a mixture of 696.5 g of Copolyester Eastar 6763 PET resin, and 3.5 g of phosphor described above, which corresponds to a weight proportion of 0.5%.

The formulation is first mixed in a rotary mixer, then is extruded in a co-rotating twin-screw extruder of Leistritz LSM 30/34 type, having a diameter of 34 mm and a length/diameter ratio of 35. The extrusion temperature is 250° C.

The films are directly processed on leaving the extruder. A sheet die is fitted onto the converging section. This makes it possible to form the extruder material into a sheet 300 mm wide and 250 μm thick.

The film-forming device is composed of:
two rolls regulated at a temperature of 70° C.;
six “support” rolls that guide the film to a winding roll on which the finished product is stored.

Optical Characterizations in the Visible

The films obtained are characterized in terms of total transmission (TT) and diffuse transmission (DT) using a Perkin Elmer UV-Vis Lambda 900 spectrometer equipped with an integrating sphere. The total and diffuse transmissions are measured over a range extending from 450 nm to 800 nm and normalized between 0 and 100%. The haze is determined by the formula:

haze (%)=DT/TT×100.

The comparative phosphor-free PET film has a total transmission of 90% over the entire range of wavelengths, while the PET-phosphor composite film has a total transmission of 88.6% in the same range of wavelengths. The transmission values given above show that the presence of the phosphor does not lead to a significant modification of the transparency.

Organic Solar Cell Based on Conjugated Polymers

The films mentioned above were then tested in OPV (organic photovoltaic) devices. The solar cell used for this test is of direct structure with anode on the front face. On a glass covered with a transparent conductive layer of ITO (indium tin oxide), a PEDOT-PSS (poly(3,4-ethylenedioxythiophene-polystyrene sulfonate) polymer film was deposited by spin-coating. The photoactive film is composed of PCDTBT (poly[N-9′-heptadecanyl-2,7-carbazole-alt-5,5-(4,7-di-2-thienyl-2′,1′,3′-benzothiadiazole), mixed with PC70BM (methyl [6,6]-phenyl-C₇₀-butanoate) in a chloroform:ortho-dichlorobenzene solvent mixture. No heat treatment was carried out.

Finally, the cathode contacts are evaporated thermally under high vacuum through a mask which defines, on each substrate, 6 pixels having 0.045 cm² of active surface area. Each pixel corresponds to a small OPV cell.

Electrical Tests

The JN tests are carried out outside of the glove box in a chamber with an inert atmosphere comprising a quartz window. The PET-phosphor films are applied to this quartz window. The measurements of the PET-phosphor film are carried out by comparison with the measurements made by applying the comparative PET film (not filled with phosphor).

The electrical tests are carried out under an illumination equivalent to 1 sun, through a standardized AM 1.5 filter. The intensity of the solar simulator is calibrated by means of a silicon photovoltaic cell. A voltage is applied to the cell (between −1.5V and 1.5V) and the current produced is measured using a Keithley current generator that makes it possible to apply an electrical field to the terminals of a system and to measure the resulting electric current.

Firstly, the comparative PET film is applied to the photovoltaic device and the absolute efficiency of the cell is recorded. Three measurements are made per sample, then the average value is taken. The same measurements are then made with the PET-phosphor film.

The absolute efficiency of the cell with the comparative PET film is r=2.54%.

The absolute efficiency of the cell with the PET-phosphor film is r=2.74%, which represents a relative increase of 7.9% in the efficiency of the cell.

### COMPARATIVE EXAMPLES

Several tests were carried out that make it possible to show that the barium aluminate according to the invention exhibits a good compromise of properties. The polymer used is the same as for example 1 and the film prepared has the same thickness of 250 μm.

### Example 2

Use of the barium aluminate (0.5%) having the following characteristics: QE=100% (at λ_{exc} of 380 nm); d50=6.5 μm. This aluminate was obtained using a flux of MgF₂ unlike the aluminate from example 1. This aluminate corresponds to the product referred to as the reference product in the measurement of QE as was described on page

### Example 3

1% of the Reference Aluminate from Example 2 is used instead of 0.5%.

30

### Example 4

Use of a barium aluminate (0.5%) identical to the reference aluminate but with the sole difference that it was not treated by calcination in the presence of MgF₂: QE=75% (at λ_{exc} of 380 nm); d50=3.3 μm.

TABLE I

| Example | d50 | QE | TT | haze | r | improvement |
|---|---|---|---|---|---|---|
| unfilled PET | — | — | 90% | 1% | 2.54% | 0% |
| 1 (invention) | 150 | 52 | 89% | 6% | 2.74% | +7.9% |
| 0.5% | | | | | | |
| 2 (comparative) | 6500 | 100 | 89% | 26% | 2.56% | +0.8% |
| 0.5% | | | | | | |
| 3 (comparative) | 6500 | 100 | 89% | 43% | 2.59% | +1.9% |
| 1.0% | | | | | | |
| 4 (comparative) | 3300 | 75 | 89% | 28% | 2.48% | −2.4% |
| 0.5% | | | | | | |

d50: nm (laser diffractometer)
QE: external quantum efficiency in % (at an excitation wavelength λ_{exc} of 380 nm)
TT: degree of transmission (%) − substantially constant over the entire range of measurement wavelengths
haze (%)
r: absolute efficiency of the cell determined under the same conditions as in example 1
improvement = (absolute efficiency of the cell − r_{ref})/r_{ref} × 100
r_{ref}: absolute efficiency of the cell with the reference film (2.54%), that is to say with the composite film of the same thickness and consisting of the same polymer and the same additives but not filled with phosphor.

It is observed that a compromise exists between the size of the particles and the efficiency QE. In order not to lose efficiency in the visible range, it is necessary for the haze of the film to be low. However, it is observed that if the mean size of the particles decreases, the efficiency QE has a tendency to decrease.

Example 1 illustrates the invention and shows that the compromise of properties enables an improvement of 7.9% for a proportion of 0.5% even though, surprisingly, the efficiency QE is lower for the aluminate from this example than for the aluminates from example 2 or from example 4.

In the case of example 3, it is observed that increasing the proportion to 1% does not make it possible to increase the improvement significantly.

### Examples 5-6

Examples 5 and 6 were carried out with EVA. Use was made of the Elvax 150 grade from Dupont (32% vinyl acetate, MFI=43 g/10 min 190° C./2.16 kg).

The composite film was obtained by extrusion of the EVA and of the phosphor of 0.5% aluminate type. The thickness of the film is 250 μm.

### Example 5

The barium aluminate from example 1 (0.5%) is used.

### Example 6

### Use of a barium aluminate (0.5%) of the same composition as the reference aluminate but that has not finished with the treatment with MgF₂: QE=75% (at λ_{exc} of 380 nm); d50=3.3 nm.

TABLE II

| Example | d50 | QE | TT | haze |
|---|---|---|---|---|
| unfilled EVA | — | — | 92% | 4% |
| 5 (invention) | 150 | 52 | 87% | 50% |
| 0.5% | | | | |
| 6 | 3300 | 100 | 87% | 74% |
| (comparative) | | | | |
| 0.5% | | | | |

Here too it is observed that the total transmission is not affected very much by the presence of the particles.

### Example 7

It was sought to reduce the d50 of the aluminate from example 2 using several customary grinding techniques, especially ball milling or wet grinding, but without being able to achieve d50<1 μm.

1. A luminescent composite comprising:
a polymer selected from ethylene/vinyl acetate (EVA), polyethylene terephthalate, ethylene tetrafluoroethylene, ethylene trifluorochloroethylene, perfluorinated ethylene-propylene, polyvinyl butyral and polyurethane;
at least one inorganic phosphor based on at least one element selected from rare earth elements, zinc and manganese, wherein the inorganic phosphor has the following characteristics:
an external quantum efficiency of greater than or equal to 40% for at least one excitation wavelength of between 350 nm and 440 nm;
an absorption of less than or equal to 10% for a wavelength of greater than 440 nm;
a mean particle size d50 of less than 1 μm;
a mean particle size d50 of at least 30 nm; and
an emission maximum in a range of wavelengths between 440 nm and 900 nm.

2. The luminescent composite as claimed in claim 1, wherein the phosphor has a mean particle size of at most 0.4 μm.

3. The luminescent composite as claimed in claim 1, wherein the particles of the phosphor have a d50 between 80 nm and 400 nm.

4. The luminescent composite as claimed in claim 1, wherein the phosphor is selected from aluminates doped by a rare earth element and/or manganese, europium-doped borophosphates, europium-doped halophosphates, cerium-doped rare earth borates, europium-doped rare earth oxysulfides, europium-doped rare earth vanadates and manganese-doped zinc compounds.

5. The luminescent composite as claimed in claim 1 one of claims 1 to 4, wherein the composite does not comprise particles of quantum dot type.

6. The luminescent composite as claimed in claim 1, wherein the phosphor results from the separation of the solid product from the liquid phase starting from a suspension of a barium magnesium aluminate consisting of substantially single-crystal particles having a mean size of between 80 nm and 400 nm.

7. The luminescent composite as claimed in claim 6, wherein the barium magnesium aluminate consists of particles having a mean size of between 100 nm and 200 nm.

8. The luminescent composite as claimed in claim 1, wherein the phosphor is an aluminate corresponding to the formula (I):
a(Ba_{1-d}M^{I}_{d}O).b(Mg₁₋ₑM²ₑO).c(Al₂O₃)
in which:
M¹ denotes a rare earth element selected from gadolinium, terbium, yttrium, ytterbium, europium, neodymium and dysprosium;
M² denotes zinc, manganese or cobalt;
a, b, c, d and e satisfy the relationships:
0.25≦a≦2; 0<b≦2; 3≦c≦9; 0≦d≦0.4 and 0≦e≦0.6.

9. The luminescent composite as claimed in claim 8, wherein the aluminate corresponds to the aforementioned formula (I) wherein a=b=1 and c=5; or a=b=1 and c=7 or a=1; b=2 and c=8.

10. The luminescent composite as claimed in claim 6, wherein the aluminate particles are in well-separated and individual form.

11. The luminescent composite as claimed in claim 6, wherein the aluminate particles have a d50/(mean size determined by XRD) ratio of less than 2.

12. The luminescent composite as claimed in claim 6, wherein the aluminate particles have a d50/(median diameter measured by TEM) ratio of less than 2.

13. The luminescent composite as claimed in claim 1, wherein the phosphor results from the separation of the solid product from the liquid phase starting from a suspension of particles of a rare earth borate, these particles being substantially single-crystal particles having a mean size of between 100 nm and 400 nm.

14. The luminescent composite as claimed in claim 8, wherein the phosphor is an aluminate obtained by a process comprising the following steps:
forming a liquid mixture comprising in the desired proportions, in water, aluminum compounds and compounds of other elements incorporated into the composition of the aluminate in the form of inorganic salts, hydroxides or carbonates, the mixture being in the form of a solution, a suspension or a gel;
spray-drying the liquid mixture to form a spray-dried product;
calcining the spray-dried product at a high enough temperature to obtain a calcined product having a crystalline phase;
wet grinding the calcined product so as to result in the aluminate in suspension;
recovering the aluminate in the form of a powder, from the suspension, by a liquid/solid separation.

15. The luminescent composite as claimed in claim 11, wherein the calcination does not occur in the presence of a flux.

16. The luminescent composite as claimed in claim 1, being in the form of a film having a thickness of between 25 μm and 800 μm.

17. A photovoltaic cell comprising a luminescent composite as claimed in claim 1.

18. A photovoltaic cell comprising a luminescent composite film as claimed in claim 16.

19. A process for converting light energy into electrical energy using a photovoltaic cell, the process comprising increasing, using the luminescent composite as claimed in claim 1, the number of solar photons that can be used by the active elements for the conversion of light energy into electricity.
